(19) United States
(12) Patent Application Publication
(10) Pub. No.: US 2022/0179312 A1
(43) Pub. Date: Jun. 9, 2022

(54) PATTERN FORMING METHOD AND METHOD FOR MANUFACTURING ELECTRONIC DEVICE

(71) Applicant: FUJIFILM Corporation, Tokyo (JP)

(72) Inventor: Toru TSUCHIHASHI, Shizuoka (JP)

(73) Assignee: FUJIFILM Corporation, Tokyo (JP)

(21) Appl. No.: 17/674,824

(22) Filed: Feb. 17, 2022

Related U.S. Application Data
(63) Continuation of application No. PCT/JP2020/031953, filed on Aug. 25, 2020.

(30) Foreign Application Priority Data
Aug. 29, 2019 (JP) 2019-156994

(51) Int. Cl. G03F 7/039; G03F 7/20; G03F 7/32

(52) U.S. Cl. CPC G03F 7/039; G03F 7/70033; G03F 7/32; G03F 7/20

(57) ABSTRACT

An object of the present invention is to provide a pattern forming method capable of forming a pattern having an excellent resolution, using a main chain scission-type resist; and a method for manufacturing an electronic device.

The pattern forming method of an embodiment of the present invention includes a step of forming a resist film on a support, using a resist composition including a polymer in which a bond of a main chain is scissed by exposure to reduce the molecular weight; a step of exposing the resist film; and a step of developing the exposed resist film using a developer, in which the developer includes an alcohol-based solvent including a branched hydrocarbon group as a main component.

### CROSS-REFERENCE TO RELATED APPLICATIONS

This application is a Continuation of PCT International Application No. PCT/JP2020/031953 filed on Aug. 25, 2020, which claims priority under 35 U.S.C. § 119(a) to Japanese Patent Application No. 2019-156994 filed on Aug. 29, 2019. The above application is hereby expressly incorporated by reference, in its entirety, into the present application.

### BACKGROUND OF THE INVENTION

### 1. Field of the Invention

The present invention relates to a pattern forming method and a method for manufacturing an electronic device. Specifically, the present invention relates to a pattern forming method which can be suitably used for ultra-microlithography processes such as a manufacture of an ultra-large-scale integrated circuit (LSI) and a high-capacity microchip; processes for manufacturing a mold structure for imprinting; and other photofabrication processes.

### 2. Description of the Related Art

In processes for manufacturing semiconductor devices such as an integrated circuit (IC) and an LSI in the related art, microfabrication by lithography using a photoresist composition has been performed. In recent years, formation of an ultrafine pattern in a nanometer region has been demanded in accordance with realization of a high degree of integration for integrated circuits. Along with this, a tendency for an exposure wavelength to be shortened, for example, from KrF light to ArF light can be seen, and development of lithography using electron beams and extreme ultraviolet (EUV) light has also currently been in progress. Furthermore, microfabrication by lithography is not limited to the manufacture of semiconductor devices, and an application thereof to a manufacture of mold structures (stampers) in so-called nanoimprint technology, and the like, are also being studied.

Lithography using these electron beams and EUV light is positioned as a next-generation pattern forming technique, and a resist pattern forming method having a high sensitivity and a high resolution has been desired.

As the photoresist composition, a chemically amplified resist including a polymer having a group that decomposes by the action of an acid to produce a polar group, and a compound that generates an acid upon irradiation with actinic rays or radiation (so-called photoacid generator) has been widely used. In addition to this, for example, a chemically amplified, negative tone resist including a crosslinkable polymer, a crosslinking agent, and a photoacid generator, in which a reaction between the polymer and the crosslinking agent proceeds by the action of an acid to form a crosslinking structure; a main chain scission-type resist including a polymer in which the main chain bond is scissed by exposure to reduce the molecular weight; a negative tone resist including low-molecular-weight compounds capable of being fused, in which the low-molecular-weight compounds are fused by exposure; and the like are used.

Among those, as the main chain scission-type resist in which a high resolution can be easily obtained, for example, a resist including a copolymer of an α-chloroacrylic acid ester-based compound and an α-methylstyrene-based compound as main components (for example, ZEP520A manufactured by Zeon Corporation), and the like are also used.

The main chain scission-type resist has a property that the polymer main chain is scissed by exposure with electron beams, EUV light, or the like, and only the exposed portion has a low molecular weight. Thus, in a case where the resist is used, a pattern is formed by a difference in the dissolution rate of the exposed portion and the non-exposed portion in a solvent.

As a developer for the main chain scission-type resist as described above, for example, n-amyl acetate (for example, ZED-N50 manufactured by Zeon Corporation), which is a carboxylic acid ester solvent having an alkyl group, is widely used. Furthermore, propylene glycol monomethyl ether acetate (PGMEA) (JP3779882B), which is a carboxylic acid ester solvent having an alkoxy group, and a solvent having at least two chemical structures of an acetic acid group, a ketone group, an ether group, and a phenyl group (JP2006-227174A) are known.

In addition, a pattern forming method using a developer including, as a main component, a carboxylic acid-based compound having a total number of carbon atoms of 8 or more, which is a carboxylic acid ester having a branched alkyl group, is also known (JP5952613B).

### SUMMARY OF THE INVENTION

The present inventors have studied a developer for a main chain scission-type resist with reference to JP3779882B, JP2006-227174A, and JP5952613B, and have found that there is room for further improving the resolution of a pattern thus formed.

Therefore, an object of the present invention is to provide a pattern forming method capable of forming a pattern having an excellent resolution, using a main chain scission-type resist.

In addition, another object of the present invention is to provide a method for manufacturing an electronic device.

The present inventors have conducted intensive studies to accomplish the objects, and as a result, they have found that the objects can be accomplished by the following configurations.

[1] A pattern forming method comprising:

a step of forming a resist film on a support, using a resist composition including a polymer in which a bond of a main chain is scissed by exposure to reduce a molecular weight;

a step of exposing the resist film; and

a step of developing the exposed resist film using a developer,

in which the developer includes an alcohol-based solvent including a branched hydrocarbon group as a main component.

[2] The pattern forming method as described in [1],

in which a CLogP of the alcohol-based solvent is 1.000 to 2.200.

[3] The pattern forming method as described in [1] or [2],

in which a total number of carbon atoms of the alcohol-based solvent is 5 to 7.

[4] The pattern forming method as described in any one of [1] to [3],

in which the alcohol-based solvent includes one oxygen atom.

[5] The pattern forming method as described in any one of [1] to [4],

in which the alcohol-based solvent is one or more selected from the group consisting of 3-methyl-2-butanol, 2-methyl-2-butanol, 2,2-dimethyl-1-propanol, 2-methyl-1-butanol, 3-methyl-1-butanol, 4-methyl-2-pentanol, 3,3-dimethyl-2-butanol, 2,3-dimethyl-2-butanol, 2-methyl-2-pentanol, 2-methyl-3-pentanol, 3-methyl-2-pentanol, 3-methyl-3-pentanol, 3,3-dimethyl-1-butanol, 2-ethyl-1-butanol, 2-methyl-1-pentanol, 3-methyl-1-pentanol, 4-methyl-1-pentanol, 3-ethyl-3-pentanol, 2,4-dimethyl-3-pentanol, 2,2-dimethyl-3-pentanol, 2,3-dimethyl-3-pentanol, 4,4-dimethyl-2-pentanol, 2-methyl-2-hexanol, 2-methyl-3-hexanol, 5-methyl-2-hexanol, and 5-methyl-1-hexanol, and a content of the alcohol-based solvent is 90% by mass or more with respect to a total mass of the developer.

[6] The pattern forming method as described in any one of [1] to [5],

in which the alcohol-based solvent is an alcohol-based solvent having a hydroxyl group substituted on a secondary carbon atom or a tertiary carbon atom.

[7] The pattern forming method as described in any one of [1] to [6], in which a total number of carbon atoms of the alcohol-based solvent is 6 or 7.

[8] The pattern forming method as described in any one of [1] to [7], in which the polymer includes an α-methylstyrene-based structural unit and an α-chloroacrylic acid ester-based structural unit.

[9] The pattern forming method as described in any one of [1] to [8],

in which the developing step is a step of performing development using a development device, and

a part or an entirety of a region in contact with the developer in the development device is formed of a fluorine-containing resin.

[10] The pattern forming method as described in any one of [1] to [9],

in which a positive tone pattern is formed.

[11] A method for manufacturing an electronic device, comprising the pattern forming method as described in any one of [1] to [10].

According to the present invention, it is possible to provide a pattern forming method capable of forming a pattern having an excellent resolution, using a main chain scission-type resist.

In addition, according to the present invention, it is also possible to provide a method for manufacturing an electronic device.

### DESCRIPTION OF THE PREFERRED EMBODIMENTS

Hereinafter, the present invention will be described in detail.

The configuration requirements described below may be explained on the basis of representative embodiments of the present invention in some cases, but the present invention is not limited to such embodiments.

In notations for a group (atomic group) in the present specification, in a case where the group is noted without specifying whether it is substituted or unsubstituted, the group includes both a group having no substituent and a group having a substituent as long as this does not impair the spirit of the present invention. For example, an “alkyl group” includes not only an alkyl group having no substituent (unsubstituted alkyl group), but also an alkyl group having a substituent (substituted alkyl group). In addition, an “organic group” in the present specification refers to a group including at least one carbon atom.

The substituent is preferably a monovalent substituent unless otherwise specified.

In the present specification, a numerical range expressed using “to” is used in a meaning of a range that includes the preceding and succeeding numerical values of “to” as the lower limit value and the upper limit value, respectively.

The bonding direction of divalent groups noted in the present specification is not limited unless otherwise specified. For example, in a case where Y in a compound represented by General Formula “X—Y—Z” is —COO—, Y may be —CO—O— or —O—CO—. That is, the compound may be “X—CO—O—Z” or “X—O—CO—Z”.

In the present specification, (meth)acrylate represents acrylate and methacrylate, and (meth)acryl represents acryl and methacryl.

In the present specification, “exposure” includes, unless otherwise specified, not only exposure using light but also lithography using particle beams such as electron beams and ion beams. In addition, examples of light used for exposure generally include actinic rays (active energy rays) such as a bright line spectrum of a mercury lamp, far ultraviolet rays typified by an excimer laser, extreme ultraviolet rays (EUV light), X-rays, and electron beams.

In the present specification, the weight-average molecular weight (Mw) and the number-average molecular weight (Mn) of a resin are each a molecular weight as converted, using tetrahydrofuran (THF) as a solvent and polystyrene as a standard substance by a gel permeation chromatography (GPC) analysis method unless otherwise specified.

In the present specification, a term “step” includes not only an independent step but also even a step which is not clearly distinguished from other steps as long as an intended purpose of the step is accomplished.

In the present specification, examples of the halogen atom include a fluorine atom, a chlorine atom, a bromine atom, and an iodine atom.

[Pattern Forming Method]

The pattern forming method of an embodiment of the present invention includes:

a step of forming a resist film on a support, using a resist composition including a polymer (hereinafter also referred to as a “specific polymer”) in which a bond of a main chain is scissed by exposure to reduce the molecular weight (hereinafter also referred to as a “resist film forming step”),

a step of exposing the resist film (hereinafter also referred to as an “exposing step”), and

a step of developing the exposed resist film using a developer (hereinafter also referred to as a “developing step”),

in which the developer includes an alcohol-based solvent including a branched hydrocarbon group (hereinafter also referred to as a “specific alcohol-based solvent”) as a main component.

A pattern formed by the pattern forming method of the embodiment of the present invention, which has the configuration, has an excellent resolution. Although being not clear in detail, it is presumed that in a case where the main component of the developer is a specific alcohol-based solvent, a penetration of the developer into the non-exposed portion is suppressed and a pattern collapse (including a pattern crush) caused by softening of the non-exposed portion can be suppressed in the exposed resist film. As a result, it is considered that the pattern formed has an excellent resolution.

Hereinafter, each procedure of the pattern forming method of the embodiment of the present invention will be described.

Moreover, according to the pattern forming method of the embodiment of the present invention, a pattern in which the exposed portion is usually removed by the developing step, that is, a positive tone pattern can be formed.

[Resist Film Forming Step (Step 1)]

Hereinafter, the resist composition and the support which can be used in the step 1 will first be described.

<Resist Composition>

The resist composition includes a polymer (specific polymer) in which a main chain bond is scissed by exposure to reduce the molecular weight.

(Specific Polymer)

The specific polymer is a polymer that reduces the molecular weight by the scission of the main chain bond upon irradiation with ionizing radiation such as electron beams, and short-wavelength light such as ultraviolet rays (for example, electron beams, KrF laser, ArF laser, and EUV laser).

As the specific polymer, a copolymer including a structural unit derived from an α-chloroacrylic acid ester-based compound (hereinafter also referred to as an “α-chloroacrylic acid ester-based structural unit”) and a structural unit derived from an α-methylstyrene-based compound (hereinafter also referred to as an “α-methylstyrene-based structural unit”) is preferable. That is, the specific polymer is preferably a copolymer including the α-chloroacrylic acid ester-based structural unit and the structural unit derived from the α-methylstyrene-based compound as the structural unit (repeating unit).

In addition, it is also preferable that the copolymer includes a fluorine atom from the viewpoint of further improving an absorption efficiency in EUV exposure. Since the fluorine atom has a property of easily absorbing EUV light, it has an effect of increasing the absorption efficiency in EUV exposure. In a case where the copolymer includes a fluorine atom, it is preferable that a structural unit including a fluorine atom is separately included in the copolymer. In other words, in a case where the copolymer includes a fluorine atom, it is preferable that the copolymer includes an α-chloroacrylic acid ester-based structural unit, an α-methylstyrene-based structural unit, and a structural unit including a fluorine atom. Furthermore, the α-chloroacrylic acid ester-based structural unit including a fluorine atom and the α-methylstyrene-based structural unit including a fluorine atom each correspond to the structural unit including a fluorine atom.

A content of the α-chloroacrylic acid ester-based structural unit (a total content of the α-chloroacrylic acid ester-based structural units in a case where a plurality thereof are included) in the copolymer is not particularly limited, but is preferably 10% to 90% by mole, and more preferably 30% to 70% by mole, with respect to all structural units of the copolymer.

In addition, a content of the α-methylstyrene-based structural unit (a total content of the α-methylstyrene-based structural units in a case where a plurality thereof are included) in the copolymer is not particularly limited, but is preferably 10% to 90% by mole, and more preferably 30% to 70% by mole, with respect to all structural units of the copolymer.

The copolymer may include any other structural unit other than the α-chloroacrylic acid ester-based structural unit and the α-methylstyrene-based structural unit.

A total content of the α-chloroacrylic acid ester-based structural unit and the α-methylstyrene-based structural unit in the copolymer is preferably 90% by mole or more, more preferably 98% by mole or more, and preferably 100% by mole (that is, the copolymer is preferably composed of only the α-chloroacrylic acid ester-based structural unit and the α-methylstyrene-based structural unit), with respect to all structural units of the copolymer.

In addition, the copolymer may be any one of a random polymer, a block polymer, and an alternating polymer (ABAB•••), for example, as long as it has the α-chloroacrylic acid ester-based structural unit and the α-methylstyrene-based structural unit, but the copolymer preferably includes 90% by mass or more (upper limit: 100% by mass) of the alternating polymer.

Since the copolymer includes the α-chloroacrylic acid ester-based structural unit and the α-methylstyrene-based structural units, the main chain is scissed to reduce the molecular weight in a case where the copolymer is irradiated with ionizing radiation such as electron beams and short-wavelength light such as ultraviolet rays (for example, electron beams, KrF laser, ArF laser, and EUV laser).

Hereinafter, various structural units constituting the copolymer will be described.

<<α-Chloroacrylic Acid Ester-Based Structural Unit>>

The α-chloroacrylic acid ester-based structural unit is a structural unit derived from an α-chloroacrylic acid ester-based compound.

Examples of the α-chloroacrylic acid ester-based compound include an unsubstituted alkyl α-chloroacrylate ester and an α-chloroacrylic acid ester derivative.

As the unsubstituted alkyl group in the unsubstituted alkyl α-chloroacrylate ester, an unsubstituted alkyl group having 1 to 10 carbon atoms is preferable, and a methyl group or an ethyl group is more preferable (furthermore, for example, in a case where the unsubstituted alkyl group in the unsubstituted alkyl α-chloroacrylate ester is the methyl group, the unsubstituted alkyl α-chloroacrylate ester is intended to be methyl α-chloroacrylate).

Examples of the α-chloroacrylic acid ester derivative include a halogen-substituted alkyl α-chloroacrylate ester, and specifically, a 2,2,2-trichloroethyl α-chloroacrylate ester, a 2,2,3,3,3-pentachloropropyl α-chloroacrylate ester, and a pentachlorophenyl α-chloroacrylate ester.

As the α-chloroacrylic acid ester-based compound, among those, the unsubstituted alkyl α-chloroacrylate ester is preferable, and methyl α-chloroacrylate or ethyl α-chloroacrylate is more preferable.

<<α-Methylstyrene-Based Compound>>

The α-methylstyrene-based structural unit is a structural unit derived from an α-methylstyrene-based compound. Examples of the α-methylstyrene-based compound include α-methylstyrene and a derivative thereof.

Examples of the α-methylstyrene derivative include 4-chloro-α-methylstyrene and 3,4-dichloro-α-methylstyrene.

As the α-methylstyrene-based compound, α-methylstyrene is preferable.

<<Structural Unit Including Fluorine Atom>>

The copolymer may further include a structural unit including a fluorine atom other than the above-mentioned α-chloroacrylic acid ester-based structural unit and α-methylstyrene-based structural unit.

Examples of the structural unit including a fluorine atom include a structural unit (hereinafter also referred to as a “structural unit F-1”) in which a fluorine atom is introduced into a part of the above-mentioned α-chloroacrylic acid ester-based structural unit; a structural unit (hereinafter also referred to as a “structural unit F-2”) in which a fluorine atom is introduced into a part of the above-mentioned α-methylstyrene-based structural unit; and another structural unit having a fluorine atom (hereinafter also referred to as a “structural unit F-3”) other than the structural unit.

Structural Unit F-1

As the structural unit (structural unit F-1) in which a fluorine atom is introduced into a part of the α-chloroacrylic acid ester-based structural unit, a structural unit derived from an fluorine-substituted alkyl α-chloroacrylate ester-based compound is preferable, and specific examples thereof include a structural unit derived from a perfluoroalkyl α-chloroacrylate ester-based compound shown below.

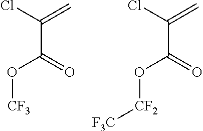

Structural Unit F-2

Examples of the structural unit (structural unit F-2) in which a fluorine atom is introduced into a part of the α-methylstyrene-based structural unit include a structural unit derived from an α-methylstyrene-based compound including a fluorine atom shown below.

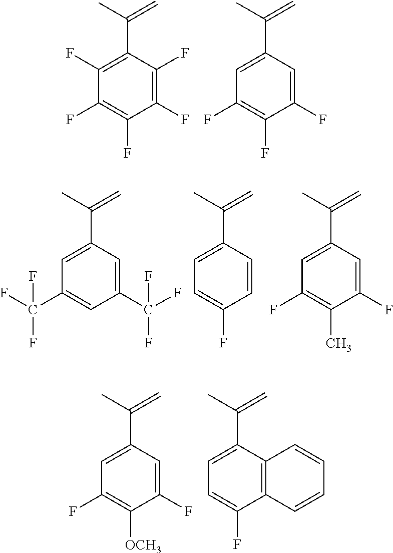

Structural Unit F-3

As another structural unit having a fluorine atom (structural unit F-3) other than the structural unit, a structural unit derived from an alkyl α-fluoroacrylate ester-based compound is preferable, and a structural unit derived from a fluorine-substituted alkyl α-fluoroacrylate ester-based compound is more preferable. Specific examples of the structural unit F-3 include a structural unit derived from an α-fluoroacrylic acid perfluoroester-based compound shown below.

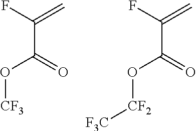

<<Other Structural Units>>

The copolymer may have various structural units, in addition to the above-mentioned structural units, for the purpose of adjusting adhesiveness to a substrate, a resist profile, heat resistance, sensitivity, and the like.

Examples of the monomers derived from such another structural unit include (meth)acrylic acid, (meth)acrylate, (meth)acrylate including a lactone structure, vinyl naphthalene, vinyl anthracene, vinyl chloride, and vinyl acetate.

The weight-average molecular weight (Mw) of the copolymer is preferably 10,000 to 1,000,000, more preferably 30,000 to 120,000, and still more preferably 50,000 to 70,000. In a case where the weight-average molecular weight of the copolymer is 10,000 or more, the solubility in a developer is not too high, and as a result, a contrast between the exposed portion and the non-exposed portion of a pattern thus formed is more excellent.

The copolymer can be synthesized according to a known method.

The copolymer is not particularly limited, and specific examples thereof include a copolymer of an unsubstituted alkyl α-chloroacrylate ester and α-methylstyrene. The copolymer is excellent in resolution and etching resistance.

Examples of the resist composition including the copolymer include ZEP520A manufactured by Zeon Corporation.

(Solvent)

The resist composition may further include a solvent in terms of improving a coating property on a substrate in the step 1.

As the solvent, a known solvent can be used as long as it is a solvent capable of dissolving the above-mentioned specific polymer. Examples of the solvent that can be used include anisole.

(Resist Composition)

The resist composition used in the step 1 includes the specific polymer as a main component.

Here, “including the specific polymer as a main component” means that a content of the specific polymer is 90% by mass or more with respect to a total solid content of the resist composition. Furthermore, in the present specification, a “solid content” in the resist composition is intended to be a component forming a resist film, and does not include a solvent. In addition, any of components that form a resist film are regarded as a solid content even in a case where they have a property and state of a liquid.

Furthermore, the resist composition may include an optional component such as a surfactant, in addition to the above-mentioned specific polymer and solvent.

A resist film formed from a resist composition including the above-mentioned specific polymer (in particular, the above-mentioned copolymer) as a main component corresponds to a so-called main chain scission-type resist film. That is, in a case where a resist film is exposed, a bond of the main chain of the specific polymer in the resist film is scissed such that the molecular weight is changed, thereby forming a reaction system in which the solubility in a developer is improved. As a result, a difference in the solubility in each of the exposed portion and the non-exposed portion serves a contrast of a pattern, and the pattern is thus formed. Furthermore, the pattern formed of the resist composition is usually a positive tone pattern.

<Support>

A material of the support used in the step 1 is not particularly limited, and for example, silicon, silicon oxide, quartz and the like can be used. Specific examples of the support include a silicon wafer, and a quartz substrate with a metal hard mask, on which the metal hard mask such as chromium is laminated.

<Resist Film Forming Step>

The step 1 is a step of forming a resist film on a support, using a resist composition.

The resist composition and the support are as described above.

In the resist composition, it is preferable that a content of metal atoms is reduced.

Hereinafter, first, a specific example of a method for reducing the content of the metal atoms in the resist composition will be described, and then a specific example of a method for preparing the resist composition will be described.

Examples of the method for reducing the content of the metal atoms in the resist composition include a method for adjusting the content by filtration using a filter. As for the filter pore diameter, the pore size is preferably less than 100 nm, more preferably 10 nm or less, and still more preferably 5 nm or less. As the filter, a polytetrafluoroethylene-made, polyethylene-made, or nylon-made filter is preferable. The filter may include a composite material in which the filter material is combined with an ion exchange medium. As the filter, a filter which has been washed with an organic solvent in advance may be used. In the step of filter filtration, plural kinds of filters connected in series or in parallel may be used. In a case of using the plural kinds of filters, a combination of filters having different pore diameters and/or materials may be used. In addition, various materials may be filtered plural times, and the step of filtering plural times may be a circulatory filtration step.

In addition, examples of a method for reducing the content of the metal atoms in the resist composition include a method of selecting raw materials having a low content of metals as raw materials constituting various materials in the resist composition, a method of subjecting raw materials constituting various materials in the resist composition to filter filtration, and a method of performing distillation under the condition for suppressing the contamination as much as possible by, for example, lining the inside of a device with TEFLON (registered trademark).

Moreover, as the method for reducing the content of the metal atoms in the resist composition, removal with an adsorbing material may be performed, in addition to the above-mentioned filter filtration, and the filter filtration and the adsorbing material may be used in combination. As the adsorbing material, known adsorbing materials can be used, and for example, inorganic adsorbing materials such as silica gel and zeolite, and organic adsorbing materials such as activated carbon can be used.

In addition, in order to reduce the content of the metal atoms in the resist composition, it is necessary to prevent the incorporation of metal impurities in the production process. Sufficient removal of metal impurities from a production device can be confirmed by measuring the content of metal components included in a washing liquid used to wash the production device.

Next, a specific example of the method for preparing the resist composition will be described.

In the production of the resist composition, for example, it is preferable to dissolve various components such as the above-mentioned resin and surfactant in a solvent, and then perform filtration (which may be circulatory filtration) using a plurality of filters having different materials. For example, it is preferable to connect a polyethylene-made filter with a pore diameter of 50 nm, a nylon-made filter with a pore diameter of 10 nm, and a polyethylene-made filter with a pore diameter of 3 to 5 nm in permuted connection, and then perform filtration. As for the filtration, a method of performing circulatory filtration twice or more is also preferable. Furthermore, the filtration step also has an effect of reducing the content of the metal atoms in the resist composition. A smaller pressure difference among the filters is more preferable, and the pressure difference is generally 0.1 MPa or less, preferably 0.05 MPa or less, and more preferably 0.01 MPa or less. A smaller pressure difference between the filter and the charging nozzle is also more preferable, and the pressure difference is generally 0.5 MPa or less, preferably 0.2 MPa or less, and more preferably 0.1 MPa or less.

In addition, as a method for performing circulatory filtration using a filter in the production of the resist composition, for example, a method of performing circulatory filtration twice or more using a polytetrafluoroethylene-made filter having a pore diameter of 50 nm is also preferable.

It is preferable to subject the inside of a device for producing the resist composition to gas replacement with an inert gas such as nitrogen. With this, it is possible to suppress dissolution of an active gas such as oxygen in the resist composition.

After being filtered by a filter, the resist composition is charged into a clean container. It is preferable that the resist composition charged in the container is subjected to refrigeration storage. This enables performance deterioration caused by the lapse of time to be suppressed. A shorter time from completion of the charge of the resist composition into the container to initiation of cold storage is more preferable, and the time is generally 24 hours or shorter, preferably 16 hours or shorter, more preferably 12 hours or shorter, and still more preferably 10 hours or shorter. The storage temperature is preferably 0° C. to 15° C., more preferably 0° C. to 10° C., and still more preferably 0° C. to 5° C.

Next, a method of forming a resist film on a support, using a resist composition, will be described.

Examples of a method of forming a resist film on a support, using the resist composition, include a method in which a resist composition is applied onto a support.

The resist composition can be applied onto a support (for example, silicon and silicon dioxide coating) as used in the manufacture of integrated circuit elements by a suitable application method such as ones using a spinner or a coater. As the application method, spin application using a spinner is preferable. A rotation speed upon the spin application using a spinner is preferably 1,000 to 3,000 rpm.

After the application of the resist composition, the support may be dried to form a resist film. In addition, various underlying films (an inorganic film, an organic film, or an antireflection film) may be formed on the underlayer of the resist film.

Examples of the drying method include a method of heating and drying. The heating may be performed using a unit included in an ordinary exposure machine and/or an ordinary development machine, and may also be performed using a hot plate or the like. A heating temperature is preferably 80° C. to 200° C. A heating time is preferably 30 to 1,000 seconds, more preferably 30 to 500 seconds, and still more preferably 30 to 300 seconds.

A film thickness of the resist film is not particularly limited, but from the viewpoint that a fine pattern having higher accuracy can be formed, the film thickness is suitably adjusted to, for example, preferably a range of 15 to 100 nm, and more preferably 20 to 40 nm.

[Exposing Step (Step 2)]

Examples of the exposing method include a method of irradiating the resist film formed with actinic rays or radiation through a predetermined mask.

Examples of the actinic rays or radiation include ultraviolet light, far ultraviolet light, extreme ultraviolet light, X-rays, and electron beams, preferably a far ultraviolet light having a wavelength of 250 mu or less, more preferably a far ultraviolet light having a wavelength of 220 nm or less, and particularly preferably a far ultraviolet light having a wavelength of 1 to 200 nm, specifically, KrF excimer laser (248 nm), ArF excimer laser (193 nm), F2 excimer laser (157 nm), EUV (13 nm), X-rays, and electron beams.

The exposure is preferably carried out, using an ultraviolet irradiation device (an exposure device using an aligner, a stepper, or an excimer laser as a light source), an electron beam exposure device, and an EUV exposure device. As the exposure device, among those, the electron beam exposure device and the EUV exposure device, which are capable of irradiating spot type beams or variable shaping type beams, are preferable.

Baking (heating) may be performed before performing development after the exposure. The baking accelerates a reaction in the exposed portion, and the sensitivity and the pattern shape are improved.

A heating temperature is preferably 80° C. to 150° C., more preferably 80° C. to 140° C., and still more preferably 80° C. to 130° C.

A heating time is preferably 10 to 1,000 seconds, more preferably 10 to 180 seconds, and still more preferably 30 to 120 seconds.

The heating may be performed using a unit included in an ordinary exposure machine and/or an ordinary development machine, and may also be performed using a hot plate or the like.

[Developing Step (Step 3)]

The step 3 is a step of developing the exposed resist film, using a developer, to form a pattern.

In the following, first, the developer used in the step 3 will be described.

<Developer>

The developer used in the step 3 includes an alcohol-based solvent including a branched hydrocarbon group (“specific alcohol-based solvent”) as a main component.

Here, “including the specific alcohol-based solvent as a main component” is intended to mean that the content of the specific alcohol-based solvent is 80% by mass or more with respect to a total mass of the developer.

Furthermore, in the developer, the specific alcohol-based solvents may be used alone or in combination of two or more kinds thereof. In a case where the developer includes a plurality of kinds of the specific alcohol-based solvents, a total content of the specific alcohol-based solvents may be 80% by mass or more with respect to the total mass of the developer (in other words, the specific alcohol-based solvents may constitute the main component of the developer).

In addition, the developer may include other components other than the main component. Examples of such other components include a surfactant.

A content of the specific alcohol-based solvent is preferably 90% by mass or more with respect to the total mass of the developer. Furthermore, an upper limit value of the content of the specific alcohol-based solvent is preferably 100% by mass or less.

Hereinafter, the specific alcohol-based solvent will be described.

The specific alcohol-based solvent may be any of a primary alcohol-based solvent (an alcohol-based solvent having a hydroxyl group substituted on a primary carbon), a secondary alcohol-based solvent (an alcohol-based solvent having a hydroxyl group substituted on a secondary carbon atom), and a tertiary alcohol-based solvent (an alcohol-based solvent having a hydroxyl group substituted on a tertiary carbon).

As the specific alcohol-based solvent, among those, a secondary alcohol or a tertiary alcohol is preferable. By using the secondary alcohol-based or tertiary alcohol-based solvent, an interaction due to hydrogen bonds caused by hydroxyl groups is more difficult to work. As a result, the interaction between the alcohol-based solvent and the pattern is suppressed, and thus, a pattern collapse is less likely to occur. That is, the resolution of the pattern is more excellent.

The total number of carbon atoms of the specific alcohol-based solvent is preferably 4 to 8, and more preferably 5 to 7. In a case where the total number of carbon atoms of the specific alcohol-based solvent is 5 or more, the boiling point is not too low, and thus, the specific alcohol-based solvent is hardly volatilized and the development unevenness during development can be further suppressed. In a case where the total number of carbon atoms is 7 or less, the boiling point is not too high, and thus, there is an advantage that the drying time after development is shorter. The total number of carbon atoms of the specific alcohol-based solvent is still more preferably 6 or 7 from the viewpoint that the resolution of a pattern thus formed is more excellent.

The branched hydrocarbon group is not particularly limited and may be either a branched saturated hydrocarbon group or a branched unsaturated hydrocarbon group, but is preferably a saturated hydrocarbon group from the viewpoint of stability.

As the branched hydrocarbon group, among those, a branched alkyl group is preferable.

The number of hydroxyl groups in the specific alcohol-based solvent is preferably one.

In addition, the number of oxygen atoms included in the specific alcohol-based solvent is preferably one. That is, it is preferable that the specific alcohol-based solvent does not include other oxygen atoms other than the oxygen atom included in one hydroxyl group.

In a case where the specific alcohol-based solvent includes another oxygen atom, which is other than the oxygen atom in the hydroxyl group, an interaction due to a hydrogen bond between such another oxygen atom (more specifically an ether group or an ester group including such another oxygen atom) and the hydroxyl group is likely to occur. By setting the number of oxygen atoms included in the specific alcohol-based solvent to one, the interaction can be suppressed. In a case where the interaction is suppressed, a pattern thus formed has a more excellent resolution, and the solubility of the polymer component having a reduction in the molecular weight, generated in the exposed portion, is more excellent. Furthermore, the volatility of the developed pattern during the drying step is more excellent.

Moreover, it is preferable that the specific alcohol-based solvent does not include another heteroatom (for example, a nitrogen atom and a sulfur atom) other than the oxygen atom.

Examples of the specific alcohol-based solvent include 3-methyl-2-butanol (ClogP: 1.002, bp: 131° C.), 2-methyl-2-butanol (ClogP: 1.002, bp: 102° C.), 2,2-dimethyl-1-propanol (ClogP: 1.092, bp: 113° C.), 2-methyl-1-butanol (ClogP: 1.222, bp: 130° C.), 3-methyl-1-butanol (ClogP: 1.222, bp: 130° C.), 4-methyl-2-pentanol (ClogP: 1.531, bp: 132° C.), 3,3-dimethyl-2-butanol (ClogP: 1.401, bp: 120° C.), 2,3-dimethyl-2-butanol (ClogP: 1.401, bp: 120° C.), 2-methyl-2-pentanol (ClogP: 1.531, bp: 121° C.), 2-methyl-3-pentanol (ClogP: 1.531, bp: 128° C.), 3-methyl-2-pentanol (ClogP: 1.531, bp: 134° C.), 3-methyl-3-pentanol (ClogP: 1.531, bp: 122° C.), 3,3-dimethyl-1-butanol (ClogP: 1.621, bp: 143° C.), 2-ethyl-1-butanol (ClogP: 1.751, bp: 146° C.), 2-methyl-1-pentanol (ClogP: 1.751, bp: 148° C.), 3-methyl-1-pentanol (ClogP: 1.751, bp: 151° C.), 4-methyl-1-Pentanol (ClogP: 1.751, bp: 163° C.), 3-ethyl-3-pentanol (ClogP: 2.06, bp: 122° C.), 2,4-dimethyl-3-pentanol (ClogP: 1.93, bp: 139° C.), 2,2-dimethyl-3-pentanol (ClogP: 1.93, bp: 132° C.), 2,3-dimethyl-3-pentanol (ClogP: 1.93, bp: 140° C.), 4,4-dimethyl-2-pentanol (ClogP: 1.93, bp: 137° C.), 2-methyl-2-hexanol (ClogP: 2.06, bp: 141° C.), 2-methyl-3-hexanol (ClogP: 2.06, bp: 142° C.), 5-methyl-2-hexanol (ClogP: 2.06, bp: 149° C.), 5-methyl-1-hexanol (ClogP: 2.28, bp: 167° C.), and 3-methyl-1-pentanol (ClogP: 1.751, bp: 151° C.).

Furthermore, the “ClogP” in parentheses is a numerical value calculated by a method which will be described later. In addition, the “bp” represents a boiling point (° C.) at normal pressure.

As the specific alcohol-based solvent, among those, one or more selected from the group consisting of 3-methyl-2-butanol, 2-methyl-2-butanol, 2,2-dimethyl-1-propanol, 2-methyl-1-butanol, 3-methyl-1-butanol, 4-methyl-2-pentanol, 3,3-dimethyl-2-butanol, 2,3-dimethyl-2-butanol, 2-methyl-2-pentanol, 2-methyl-3-pentanol, 3-methyl-2-pentanol, 3-methyl-3-pentanol, 3,3-dimethyl-1-butanol, 2-ethyl-1-butanol, 2-methyl-1-pentanol, 3-methyl-1-pentanol, 4-methyl-1-pentanol, 3-ethyl-3-pentanol, 2,4-dimethyl-3-pentanol, 2,2-dimethyl-3-pentanol, 2,3-dimethyl-3-Pentanol, 4,4-dimethyl-2-pentanol, 2-methyl-2-hexanol, 2-methyl-3-hexanol, 5-methyl-2-hexanol, and 5-methyl-1-hexanol is preferable.

As the specific alcohol-based solvent, among those, the secondary or tertiary alcohol is preferable, and specifically, one or more selected from the group consisting of 3-methyl-2-butanol, 2-methyl-2-butanol, 4-methyl-2-pentanol, 3,3-dimethyl-2-butanol, 2,3-dimethyl-2-butanol, 2-methyl-2-pentanol, 2-methyl-3-pentanol, 3-methyl-2-pentanol, 3-methyl-3-pentanol, 3-ethyl-3-pentanol, 2,4-dimethyl-3-pentanol, 2,2-dimethyl-3-pentanol, 2,3-dimethyl-3-pentanol, 4,4-dimethyl-2-pentanol, 2-methyl-2-hexanol, 2-methyl-3-hexanol, and 5-methyl-2-hexanol is more preferable.

In addition, for the specific alcohol-based solvent, it is also preferable that the CLogP is 1.000 or more from the viewpoint that a resolution formed is more excellent.

A case where the CLogP of the specific alcohol-based solvent is 1.000 or more means that the hydrophilicity is relatively low and the polarity is low. There is a tendency that the lower the polarity of the specific alcohol-based solvent (a case where the CLogP is 1.000 or more), the weaker the interaction between the specific alcohol-based solvents and the interaction between the pattern and the specific alcohol-based solvent. As a result, a capillary force between patterns during drying after development is less likely to be generated, and pattern collapse is less likely to occur.

Therefore, a lower limit value of the CLogP is preferably 1.000 or more, more preferably 1.100 or more, and still more preferably 1.200 or more.

An upper limit value of the CLogP of the specific alcohol-based solvent is preferably 2.200 or less.

In a case where the CLogP of the specific alcohol-based solvent is 2.200 or less, the generation of static electricity is suppressed, and it is difficult for the generated static electricity to stay in the specific alcohol-based solvent upon the contact between a member such as a piping tube, a valve, and a filter made of a highly insulating material such as a polyethylene resin, a polypropylene resin, a polyethylene-polypropylene resin, and a fluorine-containing resin used in a development device, and the specific alcohol-based solvent. As a result of suppressing the static electricity, it is possible to prevent the risk of a damage to a liquid contact member and/or the contamination of the liquid due to electric discharge in the pipe.

Furthermore, from the viewpoint of further preventing the risk of the damage to the liquid contact member due to electric discharge in the pipe and/or the contamination of the liquid, an upper limit value of the CLogP is more preferably 2.000 or less, and still more preferably 1.800 or less.

In addition, the “CLogP” can be calculated by ChemDraw (version. 16, manufactured by PerkinElmer Inc.).

The developing method is not particularly limited, and for example, a dip method, a spray method, a puddle method, a dynamic developing method in which a developing chemical liquid is supplied onto a wafer while rotating the wafer, or the like can be used.

<Development Device>

It is preferable that the developing step is carried out using a development device conforming to the development method.

With regard to the development device, it is preferable that a part or an entirety of a region (for example, various piping tubes, valves, and developer storage containers) in contact with a developer in the development device is formed of a resin such as a polyethylene resin, a polypropylene resin, a polyethylene-polypropylene resin, and a fluorine-containing resin in order to prevent metal contamination of the developer. That is, it is preferable that a member corresponding to the region in contact with the developer in the development device is formed of the above-mentioned resin. As the resin, among those, the fluorine-containing resin is preferable. Examples of the fluorine-containing resin include a tetrafluoroethylene resin (PTFE), a tetrafluoroethylene-perfluoroalkyl vinyl ether copolymer (PFA), a tetrafluoroethylene-hexafluoropropylene copolymerized resin (FEP), a tetrafluoroethylene-ethylene copolymerized resin (ETFE), a trifluoroethylene chloride-ethylene copolymerized resin (ECTFE), a polyvinylidene fluoride resin (PVDF), a polychlorotrifluoroethylene copolymerized resin (PCTFE), and a polyvinyl fluoride resin (PVF).

<Development Conditions>

A development time is preferably adjusted appropriately in the range of, for example, 5 to 200 seconds, and is more preferably 5 to 60 seconds.

A development temperature is preferably adjusted appropriately in the range of, for example, 18° C. to 30° C., and is more preferably around 23° C.

[Other Steps]

It is preferable that the pattern forming method includes a step of performing washing using a rinsing liquid after the step 3.

As the rinsing liquid used in the rinsing step after the step of performing development using the developer, it is preferable to use a solvent having a lower boiling point and a lower solubility than the developer in terms of achieving both defect suppression and resolution performance. As the solvent, water, an organic solvent, and a mixed liquid thereof can be used. In addition, the rinsing liquid may include a surfactant. As the rinsing liquid, specifically, isopropyl alcohol, a mixed liquid of isopropyl alcohol and water, an aqueous solution including a surfactant, or the like can be used.

A method for the rinsing step is not particularly limited, and examples thereof include a rotation application method, a dip method, and a spray method.

In addition, the pattern forming method of the embodiment of the present invention may include a heating step after the rinsing step. By the present step, the developer and the rinsing liquid remaining between and inside the patterns are removed by baking. In addition, the present step also has an effect that a resist pattern is annealed and the surface roughness of the pattern is improved. The heating step after the rinsing step is usually performed at 40° C. to 250° C. (preferably 90° C. to 200° C.) for usually 10 seconds to 3 minutes (preferably 30 to 120 seconds).

In addition, an etching treatment on the substrate may be carried out using a pattern formed as a mask. That is, the substrate (or the underlayer film and the substrate) may be processed using the pattern thus formed in the step 3 as a mask to form a pattern on the substrate.

A method for processing the substrate (or the underlayer film and the substrate) is not particularly limited, but a method in which a pattern is formed on a substrate by subjecting the substrate (or the underlayer film and the substrate) to dry etching using the pattern thus formed in the step 3 as a mask is preferable.

The dry etching may be one-stage etching or multi-stage etching. In a case where the etching is etching including a plurality of stages, the etchings at the respective stages may be the same treatment or different treatments.

For etching, any of known methods can be used, and various conditions and the like are appropriately determined according to the type of a substrate, usage, and the like. Etching can be carried out, for example, in accordance with Journal of The International Society for Optical Engineering (Proc. of SPIE), Vol. 6924, 692420 (2008), JP2009-267112A, and the like. In addition, the etching can also be carried out in accordance with “Chapter 4 Etching” in “Semiconductor Process Text Book, 4^{th} Ed., published in 2007, publisher: SEMI Japan”.

A method for improving the surface roughness of a pattern may be applied to a pattern formed by the method of the embodiment of the present invention. Examples of the method for improving the surface roughness of the pattern include the method of treating a pattern by a plasma of a hydrogen-containing gas disclosed in WO2014/002808A. Additional examples of the method include known methods as described in JP2004-235468A, US2010/0020297A, JP2008-83384A, and Proc. of SPIE Vol. 8328 83280N-1 “EUV Resist Curing Technique for LWR Reduction and Etch Selectivity Enhancement”.

In a case where a pattern formed is in the form of a line, an aspect ratio determined by dividing the height of the pattern with the line width is preferably 2.5 or less, more preferably 2.1 or less, and still more preferably 1.7 or less.

In a case where a pattern formed is in the form of a trench (groove) pattern or a contact hole pattern, an aspect ratio determined by dividing the height of the pattern with the trench width or the hole diameter is preferably 4.0 or less, more preferably 3.5 or less, and still more preferably 3.0 or less.

The pattern forming method of the embodiment of the present invention can also be used for forming a guide pattern in a directed self-assembly (DSA) (see, for example, ACS Nano Vol. 4, No. 8, Pages 4815-4823).

In addition, a pattern formed by the method can be used as a core material (core) of the spacer process disclosed in, for example, JP1991-270227A (JP-H03-270227A) and JP2013-164509A.

[Method for Manufacturing Electronic Device]

In addition, the present invention further relates to a method for manufacturing an electronic device, including the above-described pattern forming method. The electronic device is suitably mounted on electric and electronic equipment (for example, home appliances, office automation (OA)-related equipment, media-related equipment, optical equipment, telecommunication equipment, and the like).

### EXAMPLES

Hereinafter, the present invention will be described in more detail with reference to Examples. The materials, the amounts of materials used, the proportions, the treatment details, the treatment procedure, and the like shown in Examples below may be appropriately modified as long as the modifications do not depart from the spirit of the present invention. Therefore, the scope of the present invention should not be construed as being limited to Examples shown below.

[Pattern Formation and Evaluation]

[Resist Film Forming Step]

First, a composition (AL412, manufactured by Brewer Science Co., Ltd.) for forming an organic base film was applied onto a 6-inch silicon wafer substrate to a thickness of 20 nm to form a coating film. Subsequently, the coating film was baked at 205° C. for 60 seconds to prepare a silicon substrate with an organic base film.

Next, a resist composition obtained by diluting ZEP520A (a main chain scission-type resist manufactured by Zeon Corporation) with anisole was prepared. This resist composition was applied onto the above-mentioned silicon substrate with an organic base film by spin coating to form a coating film. By baking this coating film at 180° C. for 60 seconds, a resist film having a thickness of 30 nm was formed on the silicon wafer.

[Exposing Step]

An exposing step was carried out on the produced silicon wafer with a resist film. Specifically, a plurality of line-and-space patterns (line/space=1/1) having a half pitch (line width) of 15 to 50 nm were drawn on the same resist film, using an EB exposure device (ELS-G100, acceleration voltage: 100 kV, manufactured by Elionix Inc.).

[Developing Step]

Next, development of the resist film after exposure was carried out. Solvents 1 to 14 in Table 1 were each used as a developer. The development conditions are as follows.

Developer jetting time: 10 seconds

Wafer rotation speed in a case of jetting a developer: 500 rotations

Spin-drying is started immediately after jetting the developer.

Spin-drying rotation speed: 2,000 rotations

Spin-drying time: 30 seconds

By the developing step, a pattern in which the exposed portion was removed, that is, a positive tone pattern was formed.

Table 1 is shown below.

Furthermore, the “CLogP” in the table is a numerical value calculated by ChemDraw (version.16, manufactured by PerkinElmer Inc.).

In addition, “bp” in the table represents a boiling point (° C.) at normal pressure.

TABLE 1

| | | | Molecular | | |
|---|---|---|---|---|---|
| | Solvent name | Structural formula | formula | CLogP | bp |
| Solvent 1 | 3-Methyl-2-butanol | 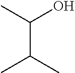 | C₅H₁₂O | 1.002 | 131 |
| Solvent 2 | 4-Methyl-2-pentanol | 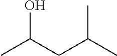 | C₆H₁₄O | 1.531 | 132 |
| Solvent 3 | 3,3-Dimethyl-2-butanol | 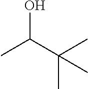 | C₆H₁₄O | 1.401 | 120 |
| Solvent 4 | 3-Ethyl-3-pentanol | 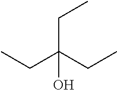 | C₇H₁₆O | 2.06 | 122 |
| Solvent 5 | 2,4-Dimethyl-3-pentanol | 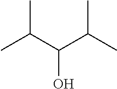 | C₇H₁₆O | 1.93 | 139 |
| Solvent 6 | 3-Methyl-1-pentanol | 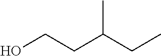 | C₆H₁₄O | 1.751 | 151 |
| Solvent 7 | Isopropanol | 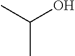 | C₃H₈O | 0.074 | 82 |
| Solvent 8 | 1-Butanol | 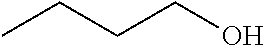 | C₄H₁₀O | 0.823 | 118 |
| Solvent 9 | N-Amyl acetate | 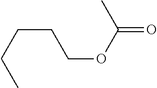 | C₇H₁₄O₂ | 2.298 | 149 |
| Solvent 10 | Propylene glycol monomethyl ether acetate | 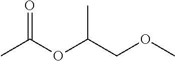 | C₆H₁₂O₃ | 0.5992 | 146 |
| Solvent 11 | Propylene glycol monomethyl ether | 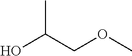 | C₄H₁₀O₂ | −0.2974 | 121 |
| Solvent 12 | Ethyl cellosolve | 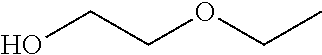 | C₄H₁₀O₂ | −0.2174 | 136 |
| Solvent 13 | 1-Heptanol | 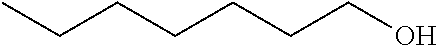 | C₇H₁₆O | 2.41 | 176 |
| Solvent 14 | 1-Nonanol | 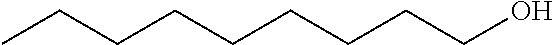 | C₉H₂₀O | 3.468 | 215 |

[Evaluation of Resolution Performance]

A plurality of the prepared line-and-space patterns having a half pitch (line width) of 15 to 50 nm were observed from the top of the patterns, using a critical dimension scanning electron microscope (SEM, S-9380II manufactured by Hitachi, Ltd.), and the resolution was evaluated. Specifically, the resolution was evaluated by a minimum line width (nm) capable of forming a line-and-space pattern in which defects caused by a pattern collapse are not generated. A smaller value thereof indicates better performance.

[Evaluation of Static Electricity Suppressing Property]

The static electricity suppressing property of the developer was evaluated based on the following evaluation standard.

A case where the CLogP value of the solvent is 2.200 or less: There is no problem (determined as A)

A case where the CLogP value of the solvent exceeds 2.200: There is a concern (determined as B)

Table 2 is shown below.

TABLE 2

| | | | Evaluation | |
|---|---|---|---|---|
| | Solvent | | Resolution | Static |
| Table 2 | No. | Solvent name | performance | electricity |
| Example 1 | Solvent 1 | 3-Methyl-2-butanol | 18 nm | A |
| Example 2 | Solvent 2 | 4-Methyl-2-pentanol | 16 nm | A |
| Example 3 | Solvent 3 | 3,3-Dimethyl-2- | 16 nm | A |
| | | butanol | | |
| Example 4 | Solvent 4 | 3-Ethyl-3-pentanol | 16 nm | A |
| Example 5 | Solvent 5 | 2,4-Dimethyl-3- | 16 nm | A |
| | | pentanol | | |
| Example 6 | Solvent 6 | 3-Methyl-1-pentanol | 20 nm | A |
| Comparative | Solvent 7 | Isopropanol | 40 nm | A |
| Example 1 | | | | |
| Comparative | Solvent 8 | 1-Butanol | 35 nm | A |
| Example 2 | | | | |
| Comparative | Solvent 9 | N-Amyl acetate | 25 nm | B |
| Example 3 | | | | |
| Comparative | Solvent | Propylene glycol | 35 nm | A |
| Example 4 | 10 | monomethyl | | |
| | | ether acetate | | |
| Comparative | Solvent | Propylene glycol | 40 nm | A |
| Example 5 | 11 | monomethyl ether | | |
| Comparative | Solvent | Ethyl cellosolve | 40 nm | A |
| Example 6 | 12 | | | |
| Comparative | Solvent | 1-Heptanol | 30 nm | B |
| Example 7 | 13 | | | |
| Comparative | Solvent | 1-Nonanol | 50 nm | B |
| Example 8 | 14 | | | |

From the results in Table 2, it is clear that a pattern formed by the pattern forming method of Examples has an excellent resolution.

Furthermore, from the comparison of Examples 1 to 5, it is clear that in a case where the total number of carbon atoms of the alcohol-based solvent is 6 or 7, the resolution of the pattern is more excellent.

In addition, from the comparison of Examples 2 to 6, it is clear that in a case where the alcohol-based solvent is a secondary alcohol or a tertiary alcohol, the resolution of the pattern is more excellent.

On the other hand, it is found that in Comparative Examples 1, 2, 5, 6, 7, and 8 in which the solvents 7, 8, 11, 12, 13, and 14 that are alcohol-based solvents including a branched structure but not having a hydrocarbon were used as the developer, and Comparative Examples 3 and 4 in which the solvents 9 and 10 that are non-alcohol-based solvents were used as the developer, the resolution of a pattern thus formed does not satisfy desired requirements.

What is claimed is:

1. A pattern forming method comprising:
a step of forming a resist film on a support, using a resist composition including a polymer in which a bond of a main chain is scissed by exposure to reduce a molecular weight;
a step of exposing the resist film; and
a step of developing the exposed resist film using a developer,
wherein the developer includes an alcohol-based solvent including a branched hydrocarbon group as a main component.

2. The pattern forming method according to claim 1,
wherein a CLogP of the alcohol-based solvent is 1.000 to 2.200.

3. The pattern forming method according to claim 1,
wherein a total number of carbon atoms of the alcohol-based solvent is 5 to 7.

4. The pattern forming method according to claim 1,
wherein the alcohol-based solvent includes one oxygen atom.

5. The pattern forming method according to claim 1,
wherein the alcohol-based solvent is one or more selected from the group consisting of 3-methyl-2-butanol, 2-methyl-2-butanol, 2,2-dimethyl-1-propanol, 2-methyl-1-butanol, 3-methyl-1-butanol, 4-methyl-2-pentanol, 3,3-dimethyl-2-butanol, 2,3-dimethyl-2-butanol, 2-methyl-2-pentanol, 2-methyl-3-pentanol, 3-methyl-2-pentanol, 3-methyl-3-pentanol, 3,3-dimethyl-1-butanol, 2-ethyl-1-butanol, 2-methyl-1-pentanol, 3-methyl-1-pentanol, 4-methyl-1-pentanol, 3-ethyl-3-pentanol, 2,4-dimethyl-3-pentanol, 2,2-dimethyl-3-pentanol, 2,3-dimethyl-3-pentanol, 4,4-dimethyl-2-pentanol, 2-methyl-2-hexanol, 2-methyl-3-hexanol, 5-methyl-2-hexanol, and 5-methyl-1-hexanol, and a content of the alcohol-based solvent is 90% by mass or more with respect to a total mass of the developer.

6. The pattern forming method according to claim 1,
wherein the alcohol-based solvent is an alcohol-based solvent having a hydroxyl group substituted on a secondary carbon atom or a tertiary carbon atom.

7. The pattern forming method according to claim 1,
wherein a total number of carbon atoms of the alcohol-based solvent is 6 or 7.

8. The pattern forming method according to claim 1,
wherein the polymer includes an α-methylstyrene-based structural unit and an α-chloroacrylic acid ester-based structural unit.

9. The pattern forming method according to claim 1,
wherein the developing step is a step of performing development using a development device, and
a part or an entirety of a region in contact with the developer in the development device is formed of a fluorine-containing resin.

10. The pattern forming method according to claim 1,
wherein a positive tone pattern is formed.

11. A method for manufacturing an electronic device, comprising the pattern forming method according to claim 1.

12. The pattern forming method according to claim 2,
wherein a total number of carbon atoms of the alcohol-based solvent is 5 to 7.

13. The pattern forming method according to claim 2,
wherein the alcohol-based solvent includes one oxygen atom.

14. The pattern forming method according to claim 2,
wherein the alcohol-based solvent is one or more selected from the group consisting of 3-methyl-2-butanol, 2-methyl-2-butanol, 2,2-dimethyl-1-propanol, 2-methyl-1-butanol, 3-methyl-1-butanol, 4-methyl-2-pentanol, 3,3-dimethyl-2-butanol, 2,3-dimethyl-2-butanol, 2-methyl-2-pentanol, 2-methyl-3-pentanol, 3-methyl-2-pentanol, 3-methyl-3-pentanol, 3,3-dimethyl-1-butanol, 2-ethyl-1-butanol, 2-methyl-1-pentanol, 3-methyl-1-pentanol, 4-methyl-1-pentanol, 3-ethyl-3-pentanol, 2,4-dimethyl-3-pentanol, 2,2-dimethyl-3-pentanol, 2,3-dimethyl-3-pentanol, 4,4-dimethyl-2-pentanol, 2-methyl-2-hexanol, 2-methyl-3-hexanol, 5-methyl-2-hexanol, and 5-methyl-1-hexanol, and a content of the alcohol-based solvent is 90% by mass or more with respect to a total mass of the developer.

15. The pattern forming method according to claim 2,
wherein the alcohol-based solvent is an alcohol-based solvent having a hydroxyl group substituted on a secondary carbon atom or a tertiary carbon atom.

16. The pattern forming method according to claim 2,
wherein a total number of carbon atoms of the alcohol-based solvent is 6 or 7.

17. The pattern forming method according to claim 2,
wherein the polymer includes an α-methylstyrene-based structural unit and an α-chloroacrylic acid ester-based structural unit.

18. The pattern forming method according to claim 2,
wherein the developing step is a step of performing development using a development device, and
a part or an entirety of a region in contact with the developer in the development device is formed of a fluorine-containing resin.

19. The pattern forming method according to claim 2,
wherein a positive tone pattern is formed.

20. A method for manufacturing an electronic device, comprising the pattern forming method according to claim 2.
